(19) United States
(12) Patent Application Publication
(10) Pub. No.: US 2014/0219749 A1
(43) Pub. Date: Aug. 7, 2014

(54) SUBSTRATE PROCESSING APPARATUS AND ROBOT CONTROLLER

(71) Applicant: KABUSHIKI KAISHA YASKAWA DENKI, Kitakyushu-shi (JP)

(72) Inventor: Shinichi KOBUCHI, Fukuoka (JP)

(73) Assignee: KABUSHIKI KAISHA YASKAWA DENKI, Kitakyushu-shi (JP)

(21) Appl. No.: 14/246,147

(22) Filed: Apr. 7, 2014

Related U.S. Application Data
(63) Continuation of application No. PCT/JP2011/077395, filed on Nov. 28, 2011.

(51) Int. Cl. H01L 21/677

(52) U.S. Cl. CPC H01L 21/67742
USPC 414/217

(57) ABSTRACT

A substrate processing apparatus includes a housing, a transfer robot, and a robot controller. The housing discharges downflow air from a bottom wall side. The transfer robot disposed inside the housing includes an elevating mechanism that vertically moves an arm section capable of holding a conveyed article. The robot controller disposed inside the housing has a cover whose two surfaces are opened, the opened two surfaces being a bottom surface and a side surface that faces a side surface on which a fan is disposed.

### CROSS-REFERENCE TO RELATED APPLICATION

The present application is a continuation application of International Application No. PCT/JP2011/077395, filed Nov. 28, 2011. The contents of these applications are incorporated herein by reference in their entirety.

### FIELD

The embodiment discussed herein is directed to a substrate processing apparatus and a robot controller.

### BACKGROUND

A known robot conveys a thin sheet-like workpiece such as a semiconductor wafer and a liquid crystal panel (hereinafter referred to as a “substrate”) and a known robot controller controls the robot. Additionally, a known substrate processing apparatus includes a robot that conveys substrates and has therein a locally clean space.

For example, Patent Literature 1 discloses a robot controller housed under a floor of a clean room in which a robot is disposed, the robot controller having an upper end portion flush with the surface of the floor.

### CITATION LIST

### Patent Literature

Patent Literature 1: Japanese Patent Application Laid-open No. H7-186075

### SUMMARY

### Technical Problem

The related-art robot controller described above is housed under the floor. This presents a problem in that a worker, when attempting to service the robot controller, finds it extremely difficult to do the service job.

Additionally, the robot controller includes a cooling fan disposed thereinside to exhaust heat generated inside the robot controller. Meanwhile, inside the clean space such as the clean room, air is cleaned by, for example, a downflow.

This requires that, when the robot controller is to be disposed in the clean room, an airflow through the clean room be prevented from being blocked by the exhaust from the robot controller.

### Solution to Problem

According to one aspect of embodiments, a substrate processing apparatus includes a housing, a transfer robot and a robot controller. The housing discharges downflow air from a bottom wall side. The transfer robot disposes inside the housing. The transfer robot includes an elevating mechanism that moves vertically within a predetermined vertical moving range an arm section that has a hand capable of holding a conveyed article. The robot controller disposed inside the housing. The robot controller includes a fan disposed on a side surface thereof. The robot controller further includes a cover whose two surfaces are opened, the opened two surfaces being a bottom surface and a side surface that faces the side surface on which the fan is disposed.

### BRIEF DESCRIPTION OF DRAWINGS

A more complete appreciation of the invention and many of the attendant advantages thereof will be readily obtained as the same becomes better understood by reference to the following detailed description when considered in connection with the accompanying drawings, wherein:

FIG. 1 is part 1 of a side elevational view illustrating a substrate processing apparatus according to a first embodiment.

FIG. 2 is a schematic perspective view illustrating a robot controller according to the first embodiment.

FIG. 3A is a top view illustrating the robot controller according to the first embodiment.

FIG. 3B is a side elevational view illustrating the robot controller according to the first embodiment.

FIG. 3C is a front elevational view illustrating the robot controller according to the first embodiment.

FIG. 4 is part 2 of the side elevational view illustrating the substrate processing apparatus according to the first embodiment.

FIG. 5 is a schematic perspective view illustrating a robot controller according to a second embodiment.

FIG. 6A is part 1 of a side elevational view illustrating a substrate processing apparatus according to the second embodiment.

FIG. 6B is part 2 of the side elevational view illustrating the substrate processing apparatus according to the second embodiment.

### DESCRIPTION OF EMBODIMENTS

Substrate processing apparatuses and robot controllers according to embodiments disclosed in this application will be described in detail below with reference to the accompanying drawings. The embodiments to be described hereunder are not intended to limit the scope of the present invention.

### First Embodiment

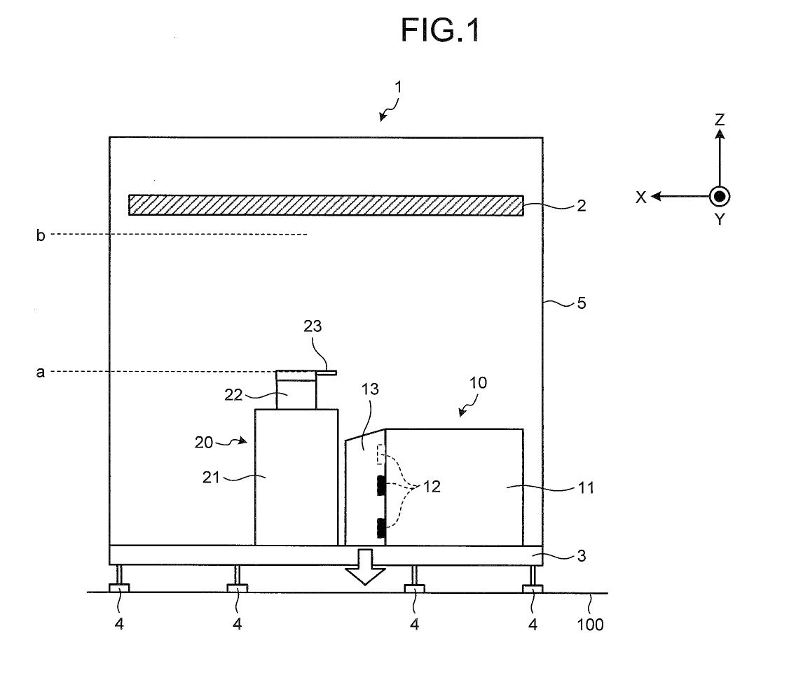

A substrate processing apparatus 1 according to a first embodiment will first be described below with reference to FIG. 1. FIG. 1 is part 1 of a side elevational view illustrating the substrate processing apparatus 1 according to the first embodiment. It is noted that the following description will be given by using coordinate axes as illustrated at the upper right part of the figure as appropriate. In the figure, shapes are partly simplified for ease of understanding.

As illustrated in FIG. 1, the substrate processing apparatus 1 includes a housing 5 and a robot mounting frame 3. The robot mounting frame 3 forms a bottom wall portion of the housing 5. A robot controller 10 and a transfer robot 20 are mounted on the robot mounting frame 3. In FIG. 1, reference numeral 100 denotes a floor surface on which the substrate processing apparatus 1 is mounted.

The substrate processing apparatus 1 is what is called an equipment front end module (EFEM) that includes a filter 2 disposed at an upper portion thereof, the filter 2 purifying a gas. A clean downward airflow purified by the filter 2 cleans the inside of the housing 5.

The robot mounting frame 3 is perforated similarly to, for example, a punching metal. The downflow air is discharged through these perforations. Leg tools 4 are disposed at a lower surface of the robot mounting frame 3 of the substrate processing apparatus 1. The leg tools 4 allow the substrate processing apparatus 1 to be supported with a predetermined distance spaced away from the floor surface 100.

This causes air discharged from the perforations in the robot mounting frame 3 to flow to a void between a lower surface of the substrate processing apparatus 1 and the floor surface 100. Additionally, the housing 5 is mounted so as to be transferred.

The transfer robot 20 includes an arm section 22 that has a hand 23 capable of holding a substrate such as a semiconductor wafer or a liquid crystal panel as a conveyed article. The arm section 22 is supported vertically movably and horizontally rotatably on a base section 21 disposed on the robot mounting frame 3 that forms the bottom wall portion of the housing 5.

The transfer robot 20 removes a substrate from a box-like cassette (not illustrated) that stores therein a plurality of substrates stacked one on top of another in the height direction and unloads the substrate into the housing 5. The cassette is disposed also inside the housing 5.

Additionally, the transfer robot 20 transfers the substrate removed from the cassette onto a predetermined processing device (not illustrated). The processing device is disposed also inside the housing 5 and performs a predetermined process of, for example, chemical vapor deposition (CVD), etching, or exposure on the substrate.

The transfer robot 20, through the foregoing configuration, can transfer the substrate placed at the hand 23 to an intended position, while moving the arm section 22 vertically from the base section 21 or rotating the arm section 22. It is noted that, as illustrated in FIG. 1, the arm section 22 moves vertically within a range between a height a and a height b.

The robot controller 10 controls operations of the transfer robot 20, including starting and stopping the transfer robot 20. The robot controller 10 includes a main unit section 11 and a cover 13. The robot controller 10 is connected to the transfer robot 20 by a cable (not illustrated). In addition, the robot controller 10 generates heat thereinside and thus includes cooling fans 12 disposed on a side surface of the main unit section 11. The robot controller 10 corresponds to means for controlling the transfer robot. The housing 5 corresponds to means for surrounding the transfer robot and the means for controlling.

The robot controller 10 is mounted on the robot mounting frame 3 and disposed to be lower than the vertical. moving range (between the height a and the height b) of the arm section 22 so as not to prevent the arm section 22 from moving.

The fans 12 exhaust air drawn in through intake holes in the main unit section 11 out of the main unit section 11. Additionally, the fans 12 are covered in the cover 13 from the side surface on which the fans 12 are disposed to the bottom surface side of the robot controller 10. It is noted that the cover 13 has a side surface and a bottom surface that are opened, the opened side surface facing the side surface on which the fans 12 are disposed.

Thus, as indicated by the arrow in FIG. 1, the air exhausted by the fans 12 escapes from the open bottom surface side of the cover 13 through the perforations in the robot mounting frame 3 downwardly of the lower surface of the substrate processing apparatus 1.

It is noted that, in the embodiment, the main unit section 11 is disposed such that the fans 12 are juxtaposed in the vertical direction (hereinafter referred to as the “vertical disposition”). The main unit section 11 may, instead, be disposed such that the fans 12 are juxtaposed in the horizontal direction (hereinafter referred to as the “horizontal disposition”).

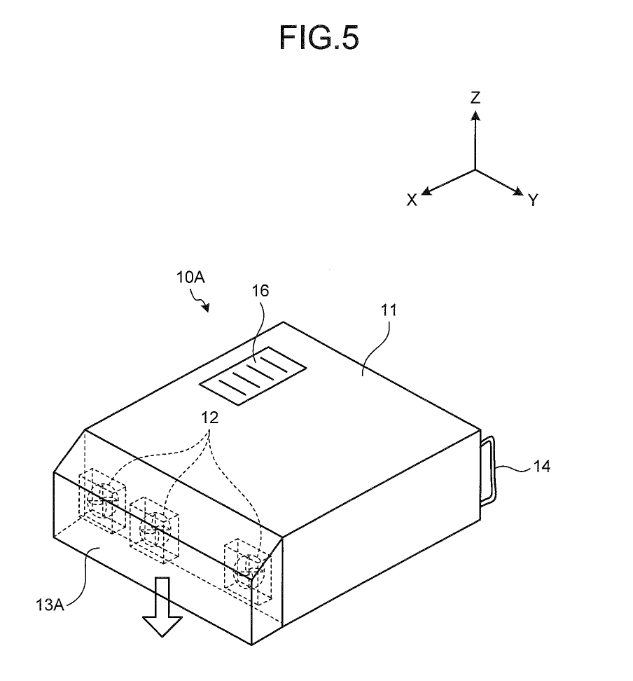

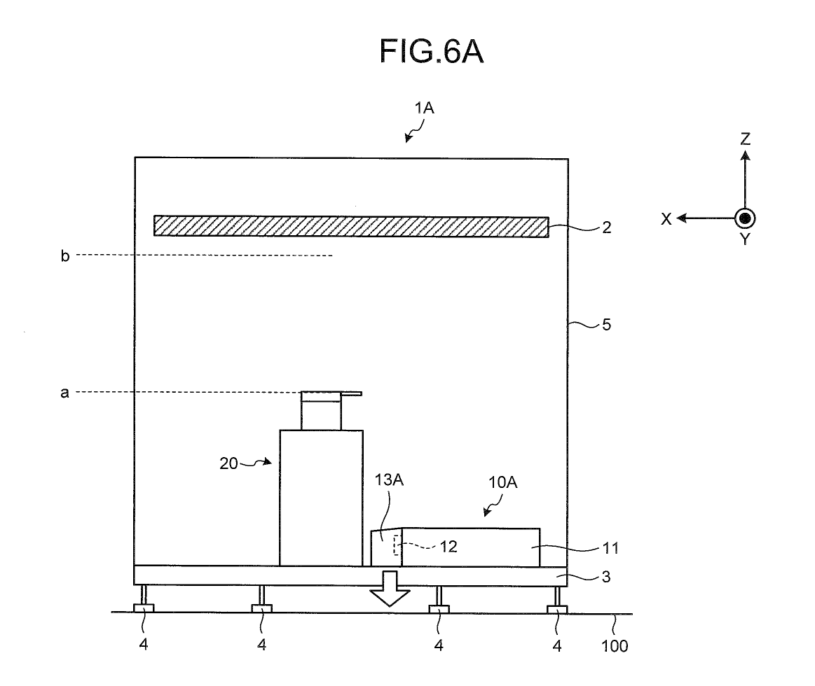

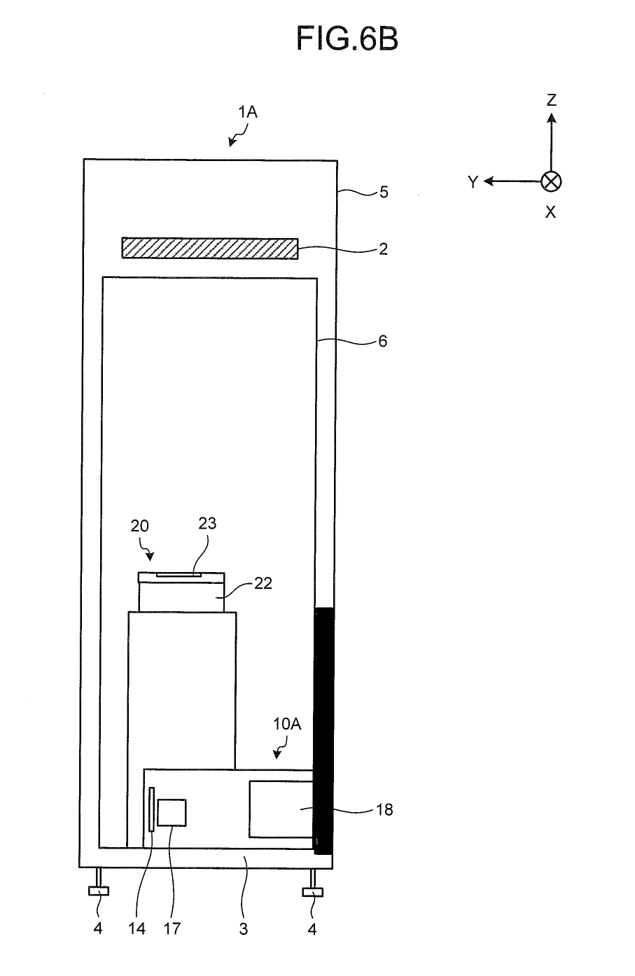

The substrate processing apparatus 1 allows the cover 13 to be replaced with a type having a bottom surface communicating according to a mounting surface of the main unit section 11. Thus, even with the main unit section 11 placed in the horizontal disposition, a cover 13 compatible with the horizontal disposition may be provided as an adjunct to thereby allow the air exhausted by the fans 12 to escape downwardly of the lower surface of the substrate processing apparatus 1. The horizontal disposition will be described in detail later with reference to FIGS. 5, 6A, and 6B.

The related-art robot controller is housed outside the substrate processing apparatus, for example, under the floor. This presents a problem in that a worker, in his or her attempt to service the robot controller, finds it extremely difficult to do the service job.

Additionally, should the robot controller be disposed inside the substrate processing apparatus, air exhausted from the fans causes fine dust and dirt contained therein to scatter around, attaching to the substrate being conveyed by the transfer robot.

If the robot controller is to be disposed inside the substrate processing apparatus, therefore, it is necessary that the airflow inside the clean room be prevented from being blocked by the exhaust from the robot controller.

Thus, in the substrate processing apparatus 1 according to the first embodiment, the fans 12 are covered by the cover 13 that has a side surface and a bottom surface that are opened, the opened side surface facing the side surface on which the fans 12 are disposed. As a result, even with the robot controller 10 disposed inside the clean substrate processing apparatus 1, the substrate processing apparatus 1 can be exhausted without the downflow clean airflow being blocked thereinside.

Additionally, the substrate processing apparatus 1 according to the first embodiment, by having the cover 13 provided as an adjunct, can prevent fine dust and dirt contained in the air exhausted from the fans 12 from attaching to the substrate.

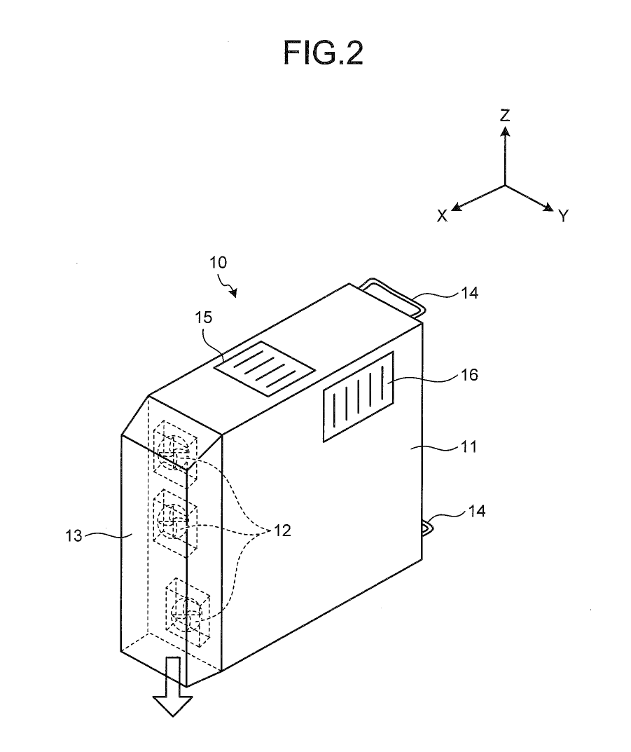

The robot controller 10 according to the first embodiment will be described in detail below with reference to FIG. 2. FIG. 2 is a schematic perspective view illustrating the robot controller 10 according to the first embodiment.

As illustrated in FIG. 2, the main unit section 11 of the robot controller 10 has handles 14 and vent holes 15, 16, each having a plurality of band-like slits formed therein. Additionally, the cover 13 covers the fans 12 from the side surface on which the fans 12 are disposed to the bottom surface side of the robot controller 10. The cover 13 is removably attached.

The robot controller 10 according to the first embodiment is disposed in the vertical disposition, specifically, disposed vertically long such that the side surface of the main unit section 11 on which the fans 12 are disposed has a longitudinal direction extending in the height direction (Z-axis direction). Additionally, the robot controller 10 has a back surface that assumes the side surface on which the fans 12 are disposed and a front surface that assumes a surface on which the handles 14 are disposed (on the negative direction side of the X-axis).

The robot controller 10 has a control circuit disposed thereinside, the control circuit including a plurality of circuit elements that control the transfer robot 20 as a controlled object. Specifically, a central processing unit (CPU), a control board, an amplifier, a converter, a relay, a capacitor, and other circuit elements (not illustrated) are disposed inside the robot controller 10.

Heat generated from these circuit elements increases the internal temperature of the robot controller 10. In order therefore to cool the heat contained inside the robot controller 10, air is drawn in through the vent holes 15, 16 and the fans 12 exhaust the drawn air out of the main unit section 11.

The cover 13 has the side surface and the bottom surface that are opened. The opened side surface faces the side surface on which the fans 12 are disposed, and the opened bottom surface is the mounting surface. Thus, the air exhausted from the fans 12 is discharged from the bottom surface side of the cover 13 as indicated by the arrow in FIG. 2.

In addition, the robot controller 10 is disposed on the robot mounting frame 3. This causes the air exhausted by the fans 12 to escape downwardly of the lower surface of the substrate processing apparatus 1 from the open bottom surface side of the cover 13 via the perforations in the robot mounting frame 3.

This enables the robot controller 10 to prevent the fine dust and dirt contained in the air exhausted from the fans 12 from scattering without blocking the airflow through the substrate processing apparatus 1.

The robot mounting frame 3 of the substrate processing apparatus 1 is perforated similarly to a punching metal. The robot mounting frame 3 may nonetheless be configured otherwise, as long as the configuration allows air to escape downwardly of the lower surface of the substrate processing apparatus 1. For example, the robot mounting frame 3 may be grated to form a lattice. Additionally, while the robot controller 10 in the embodiment includes three fans 12 disposed on the back surface side thereof, the robot controller 10 may include any number of fans as long as it has at least one.

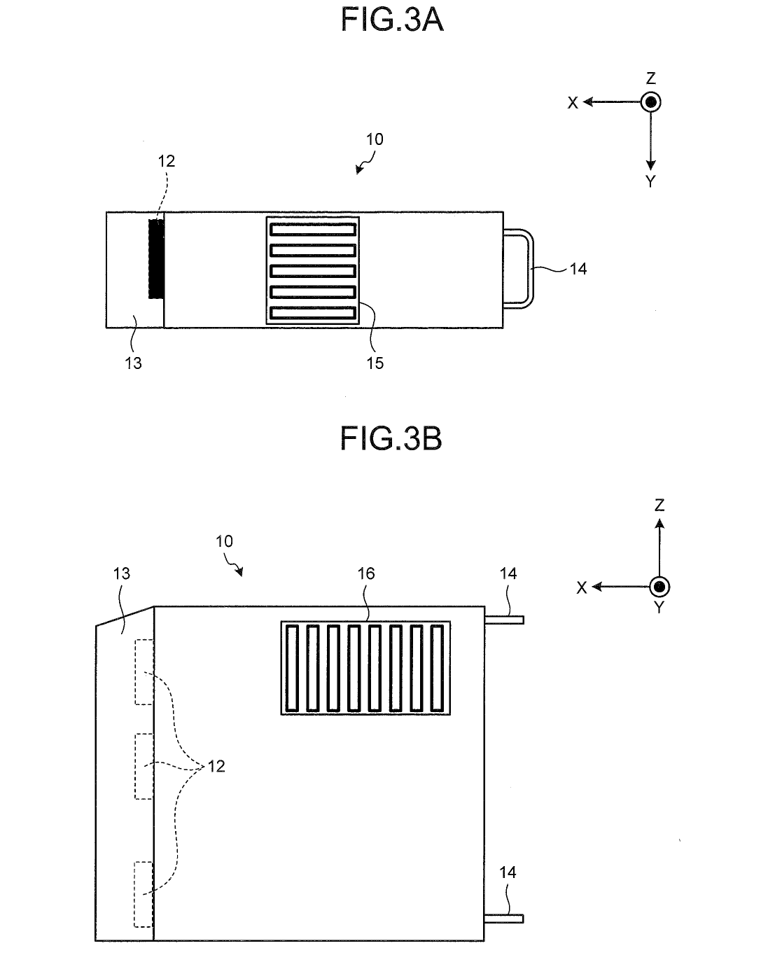

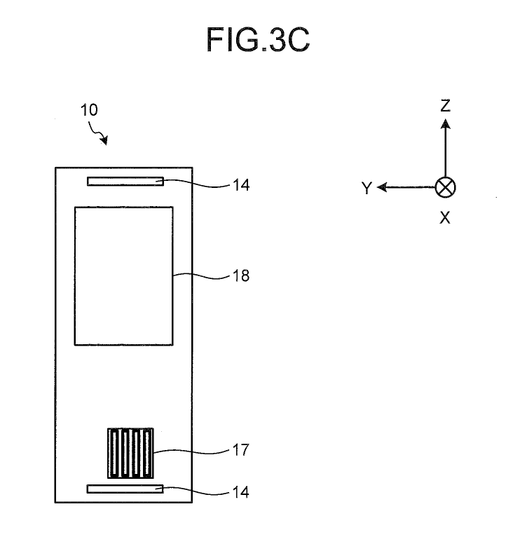

The robot controller 10 as viewed from upper, lateral, and front directions will be described below with reference to FIGS. 3A to 3C. FIG. 3A is a top view illustrating the robot controller 10 according to the first embodiment. FIG. 3B is a side elevational view illustrating the robot controller 10 according to the first embodiment. FIG. 3C is a front elevational view illustrating the robot controller 10 according to the first embodiment.

First, as illustrated in FIG. 3A, the robot controller 10 has an upper surface that has the vent hole 15 having a plurality of band-like slits formed therein. In addition, as illustrated in FIG. 3B, the robot controller 10 has a side surface that has the vent hole 16 having a plurality of band-like slits formed therein as in the upper surface.

As illustrated in FIG. 3C, the robot controller 10 has the front surface that has a vent hole 17 having a plurality of band-like slits formed therein, a control panel 18, and the handles 14 disposed at upper and lower portions thereof.

The control panel 18 includes an operating unit operated to control operations, including starting and stopping, of the transfer robot 20, a battery holder, and various types of connectors such as an input/output module and a serial communication module (not illustrated).

Each of the vent holes 15, 16, 17 has a plurality of band-like slits formed therein. This is, however, not the only possible configuration. Alternatively, for example, the vent holes 15, 16, 17 may each have round holes or rectangular holes, or even mesh holes, formed therein.

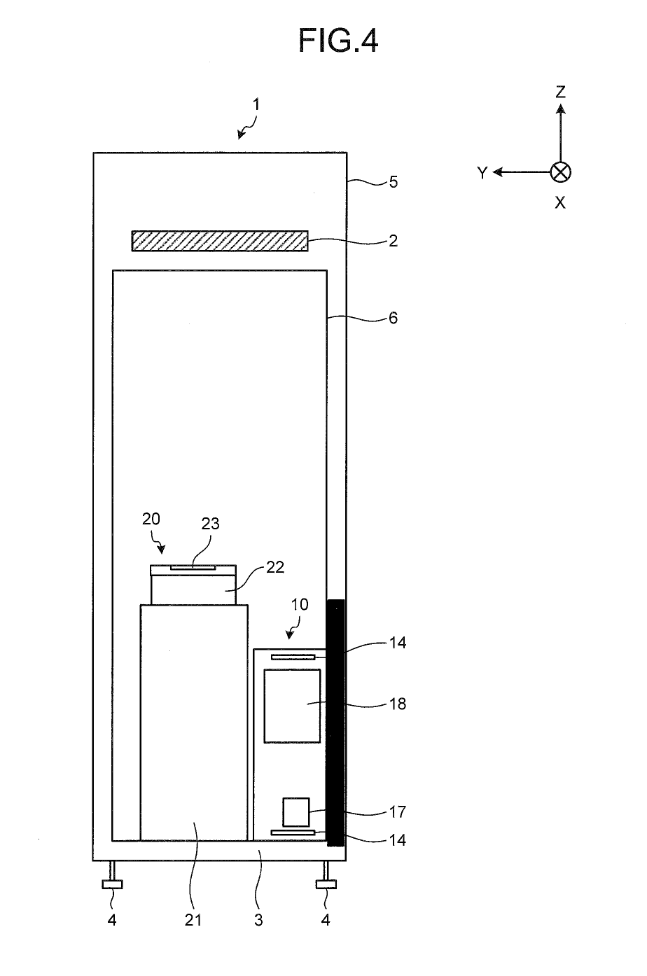

The substrate processing apparatus 1 as viewed laterally will be described below with reference to FIG. 4. FIG. 4 is part 2 of the side elevational view illustrating the substrate processing apparatus 1 according to the first embodiment. It is noted that the housing 5 has a door 6 disposed on a side surface thereof on the negative direction side of the X-axis and FIG. 4 illustrates a condition in which the door 6 is left open.

Referring to FIG. 4, the robot controller 10 and the transfer robot 20 are disposed on the robot mounting frame 3. As illustrated in the figure, the robot controller 10 is disposed so that the control panel 18 is disposed on the door 6 side (the negative direction side of the X-axis).

This allows the worker to open the door 6 and to operate smoothly to control the transfer robot 20. Furthermore, the robot controller 10 is disposed to be lower than the vertical moving range of the arm section 22 so as not to prevent the arm section 22 from moving.

As described heretofore, in the substrate processing apparatus and the robot controller according to the first embodiment, the robot controller is disposed on the robot mounting frame of the substrate processing apparatus, the robot mounting frame being perforated similarly to a punching metal. Additionally, the fans of the robot controller according to the first embodiment are covered by the cover that has the side surface and the bottom surface that are opened, the opened side surface facing the side surface on which the fans are disposed. This allows the air exhausted by the fans to escape from the open bottom surface side of the cover downwardly of the lower surface of the substrate processing apparatus via the perforations in the robot mounting frame.

The foregoing arrangements enable the substrate processing apparatus and the robot controller according to the first embodiment to exhaust without blocking the clean airflow inside the clean space, even with the robot controller disposed in the clean space.

As noted earlier, the robot controller 10 according to the above-described first embodiment is disposed in the vertical disposition. The robot controller 10 may nonetheless be disposed in the horizontal disposition, specifically, disposed transversely long such that the side surface on which the fans 12 are disposed has a transverse direction extending in the height direction. A second embodiment to be described below will be described for a case in which the robot controller is disposed in the horizontal disposition.

### Second Embodiment

A robot controller 10A according to the second embodiment will be described below with reference to FIGS. 5, 6A, and 6B. FIG. 5 is a schematic perspective view illustrating the robot controller 10A according to the second embodiment. FIGS. 6A and 6B are part 1 and part 2, respectively, of side elevational views illustrating a substrate processing apparatus 1A according to the second embodiment.

The substrate processing apparatus 1A and the robot controller 10A according to the second embodiment differ from the substrate processing apparatus 1 and the robot controller 10 according to the first embodiment in that a cover included therein is compatible with the horizontal disposition of the robot controller 10A in the substrate processing apparatus 1A.

It is noted that a housing 5, a transfer robot 20, and a main unit section 11 of the robot controller 10A have configurations similar to those in the first embodiment (FIG. 1 or 2) and descriptions of configurations of members similar to those in the first embodiment will be omitted.

As illustrated in FIG. 5, the robot controller 10A is disposed in the horizontal disposition. Fans 12 are covered in a cover 13A compatible with the horizontal disposition from a side surface on which the fans 12 are disposed to a bottom surface side of the robot controller 10A.

It is noted that the cover 13A has a bottom surface shaped differently from that of the removable cover 13 according to the first embodiment. Thus, for the horizontal disposition, the cover 13 is to be replaced with the cover 13A.

Similarly to the cover 13 in the first embodiment, the cover 13A has a side surface and a bottom surface that are opened. The opened side surface faces the side surface on which the fans 12 are disposed, and the opened bottom surface is the mounting surface. Thus, air exhausted from the fans 12 is discharged from the bottom surface side of the cover 13A as indicated by the arrow in FIG. 5.

As illustrated in FIG. 6A, the robot controller 10A is disposed on a robot mounting frame 3 that forms a bottom wall portion of the housing 5. This causes the air exhausted by the fans 12 to escape downwardly of a lower surface of the substrate processing apparatus 1A from the open bottom surface side of the cover 13A via perforations in the robot mounting frame 3 as indicated by the arrow in the figure.

FIG. 6B illustrates a condition in which a door 6 disposed on a side surface of the housing 5 on the negative direction side of the X-axis is left open. As illustrated in the figure, the robot controller 10A and the transfer robot 20 are disposed on the robot mounting frame 3.

It is noted that the robot controller 10A is disposed so that a control panel 18 is disposed on the door 6 side (the negative direction side of the X-axis). Additionally, the robot controller 10A is disposed to be lower than the vertical moving range of an arm section 22. This allows a worker to open the door 6 and to operate smoothly to control the transfer robot 20 without the robot controller 10A interfering with movement of the arm section 22.

As described above, in the second embodiment, the covers having different shapes from each other are changed as appropriate depending on the mounting direction of the robot controller. This enables the substrate processing apparatus and the robot controller according to the second embodiment to exhaust without blocking the clean airflow inside the clean space, even with the robot controller disposed in the clean space.

It should be noted that, in the embodiment, the robot controller is disposed such that the bottom surface thereof is in contact with the robot mounting frame. This is, however, not the only possible arrangement. Alternatively, for example, the robot controller may be disposed such that a void having a predetermined height is provided between the bottom surface of the robot controller and the robot mounting frame. Still, the robot controller needs to be disposed to be lower than the vertical moving range of the arm section.

In addition, the cover is shaped like a box that has the side surface and the bottom surface that are opened. The opened side surface faces the side surface on which the fans are disposed, and the opened bottom surface is the mounting surface. This is, however, not the only possible configuration. For example, the cover may have a plurality of fins on the inside and near the fans, the fins, each having a gradient extending from an upper portion toward the bottom surface side.

This causes the air exhausted by the fans to tend to flow from the open bottom surface of the cover toward the perforations in the robot mounting frame, allowing the air to escape downwardly of the lower surface of the substrate processing apparatus easily via the perforations. Thus, effect on the downflow clean airflow through the substrate processing apparatus can be minimized.

Additionally, air is drawn in through the vent holes formed in the main unit section of the robot controller. Another possible arrangement is to open or close a predetermined intake hole based on the mounting direction. For example, in the substrate processing apparatus and the robot controller according to the embodiment, slits in the intake hole formed in the upper surface portion of the robot controller are closed. Closing the intake hole formed in the upper surface portion allows the downflow clean airflow from the upper portion of the substrate processing apparatus to be prevented from flowing into the intake hole.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A substrate processing apparatus comprising:
a housing that discharges downflow air from a bottom wall side;
a transfer robot disposed inside the housing, the transfer robot including an elevating mechanism that moves vertically within a predetermined vertical moving range an arm section that has a hand capable of holding a conveyed article; and
a robot controller disposed inside the housing, the robot controller including a fan disposed on a side surface thereof, wherein
the robot controller further includes a cover whose two surfaces are opened, the opened two surfaces being a bottom surface and a side surface that faces the side surface on which the fan is disposed.

2. The substrate processing apparatus according to claim 1, wherein the cover is selected from among a plurality of types of the cover made available for use in advance, on the basis of which of surfaces of the robot controller is the bottom surface.

3. The substrate processing apparatus according to claim 1, wherein the robot controller is disposed to be lower than the vertical moving range of the elevating mechanism of the transfer robot.

4. The substrate processing apparatus according to claim 2, wherein the robot controller is disposed to be lower than the vertical moving range of the elevating mechanism of the transfer robot.

5. The substrate processing apparatus according to claim 1 wherein the housing is spaced from a floor surface.

6. The substrate processing apparatus according to claim 2, wherein the housing is spaced from a floor surface.

7. The substrate processing apparatus according to claim 3, wherein the housing is spaced from a floor surface.

8. The substrate processing apparatus according to claim 4, wherein the housing is spaced from a floor surface.

9. A robot controller comprising:
a fan disposed on a side surface thereof; and
a cover whose two surfaces are opened, the two surfaces being a bottom surface and a side surface that faces the side surface on which the fan is disposed.

10. A substrate processing apparatus comprising:
a transfer robot including an elevating mechanism that moves vertically within a predetermined vertical moving range an arm section that has a hand capable of holding a conveyed article;
means for controlling the transfer robot; and
means for surrounding the transfer robot and the means for controlling, wherein
the means for surrounding discharges downflow air from a lower part thereof, and
the means for controlling includes a fan disposed on a side surface thereof and a cover whose two surfaces are opened, the opened two surfaces being a bottom surface and a side surface that faces the side surface on which the fan is disposed.
